(19) United States
(12) Patent Application Publication
(10) Pub. No.: US 2009/0098728 A1
(43) Pub. Date: Apr. 16, 2009

(54) STRUCTURE CU LINER FOR INTERCONNECTS USING A DOUBLE-BILAYER PROCESSING SCHEME

(76) Inventors: Stephan Grunow, Poughkeepsie, NY (US); Thomas McCarroll Shaw, Peekskill, NY (US); Andrew H. Simon, Fishkill, NY (US); Chih-Chao Yang, Poughkeepsie, NY (US); Tiblor Bolom, Fishkill, NY (US); James Werking, Hopewell Junction, NY (US)

Correspondence Address: FREDERICK W. GIBB, III;Gibb Intellectual Property Law Firm, LLC, 2568-A RIVA ROAD, SUITE 304, ANNAPOLIS, MD, 21401, US

(21) Appl. No.: 11/870,649

(22) Filed: Oct. 11, 2007

(51) Int. Cl. H01L 21/4763

(52) U.S. Cl. 438/629; 257/E21.495

(57) ABSTRACT

The disclosed method forms a via between metallization layers in a semiconductor structure by patterning an insulator layer overlying a first metallization layer to include a via opening. The method lines the via opening with TaN and Ta liners and then sputter etches the via opening deeper through the TaN and Ta liners into the first metallization layer. After sputter etching, the method then lines the via opening with second TaN and Ta liners. Next, the method deposits a conductor into the via opening, thereby connecting the first and second metallization layers.

### BACKGROUND AND SUMMARY

The embodiments of the invention generally relate to conductive lines within a semiconductor structure are more particularly to an improved method of forming anchored via.

Anchoring of vias (conductors that interconnect different wiring levels in integrated circuit structures) can be achieved using a physical sputter-etch, with for example an Argon plasma. In order to provide adequate barrier coverage for the dielectric surfaces exposed during the anchor etch, a final barrier-material deposition can be done after the sputter etch, so that the dielectric surfaces exposed during the anchor etch are not put in contact with the via conductor material (e.g., Cu) during the subsequent seedlayer and electroplating steps.

Various embodiments of this via anchoring approach have been described in the literature (e.g., see U.S. Pat. Nos. 5,933,753 and 5,985,762 (hereinafter “U.S. Patents”), incorporated herein by reference) and a detailed discussion of such techniques is omitted herefrom for sake of brevity. A common embodiment is described by U.S. Patents in which a sequence includes the following steps: 1) TaN deposition, 2) Ta Deposition, 3) Ar sputter etch for anchoring purposes and 4) Final barrier-layer deposition of Ta.

A particularly demanding application for this type of scheme is the case when porous, ultra-low (K<2.5) dielectrics are used. Owing to the structural vulnerabilities of these dielectrics, and the particular need for barrier-layer isolation of Cu and ULK Dielectric in these cases, achieving a reliable interconnect with good barrier properties for this application presents a particular challenge.

In view of the foregoing, the disclosed method forms a via between metallization layers in a semiconductor structure by patterning an insulator layer overlying a first metallization layer to include a via opening. The method lines the via opening with TaN and Ta liners and then sputter etches the via opening deeper through the TaN and Ta liners into the first metallization layer. After sputter etching, the method then lines the via opening with second TaN and Ta liners. Next, a conductor is deposited into the via opening, thereby connecting the first and second metallization layers. This improves wettability and fill characteristics of the anchored via structure.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications. In order to build reliable Cu interconnects in integrated circuits, one proven method is to use a physical anchoring of the via in the line below.

### BRIEF DESCRIPTION OF THE DRAWINGS

The embodiments of the invention will be better understood from the following detailed description with reference to the drawings, in which:

FIG. 1 is a schematic cross-sectional view diagram of a conductive line in a semiconductor structure according to embodiments herein;

FIG. 2 is a schematic cross-sectional view diagram of a conductive line in a semiconductor structure according to embodiments herein;

FIG. 3 is a schematic cross-sectional view diagram of a conductive line in a semiconductor structure according to embodiments herein; and

FIG. 4 is a schematic cross-sectional view diagram of a conductive line in a semiconductor structure according to embodiments herein.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, this disclosure presents a modification to the anchor-etch barrier scheme that enables enhanced barrier performance by modifications and enhancements to the final barrier deposition sequence. For a point of reference, we compare the published U.S. Patents methods mentioned above with the following process flow: TaN/Ta deposition (initial bilayer), Ar+ Sputter etch to establish via anchoring, Ta Deposition (sometimes referred to as “Ta flash” Deposition), and Cu seedlayer deposition. In contrast, in the present disclosure, we present the following process flows: TaN/Ta deposition (TaN-only is also a possibility), Ar+ sputter etch to establish via anchoring, TaN/Ta deposition (“Bilayer Flash”), or alternatively, TaN/Ru or TaN/Ta/Ru or TaN/(Ta/PGM alloy) bilayer deposition, and Cu seedlayer deposition, where needed.

Some advantages of this revised process flow are that the TaN/Ta “Bilayer flash” allows for the full coverage of the TaN barrier layer around portions of the feature that may have exposed dielectric (resulting from the Ar+ sputter clean). By adding a second TaN layer, post Ar+ sputter etch, we are able to ensure that the full benefit of the TaN barrier is realized at every point along the barrier/dielectric interface. Regardless of whether the final barrier layer before Cu seedlayer is Ta, Ru or Ta/PGM alloys, the same benefit is achieved. In contrast, in the earlier methods, it is possible to have points along the dielectric interface where the conventional Ta flash layer contacts the dielectric interface directly, with concomitant degradation of barrier functionality.

In addition, the second TaN layer deposition post-Ar+ sputter etch ensures full conversion of the Ta flash layer to the low-resistance alpha-Ta (in the TaN/Ta bilayer case) at all points along the Ta/Cu interface, with the associated benefit of current redundancy for electromigration failure resistance.

With reference to the liner, the method for constructing the liner described above can be as follows. A BEOL dual-damascene structure without barrier/seed metal is introduced into the metal dep tool. Then, degasing may be performed. An initial layer of TaN and typically also Ta is then deposited conformally on the structure. In order to give structural gouging of the via into the Cu interconnect below, an Ar+ sputter etch is performed on the structure. This can be done in a separate sputter-etch chamber, or as part of a multi-step sequence done in-situ in a deposition chamber with etchback capability.

To the contrary, in previous methods, the first layer deposited after the punch-thru etch is only the Ta layer. The difficulty with such conventional methods is that they put dielectric surfaces exposed by the sputter etch (e.g. the trench bottom as shown by the schematic) in direct contact with the Ta layer without the benefit of a TaN layer. This conventional configuration is suboptimal for barrier properties and alpha-Ta formation, which can be critical in demanding applications such as ULK dielectrics.

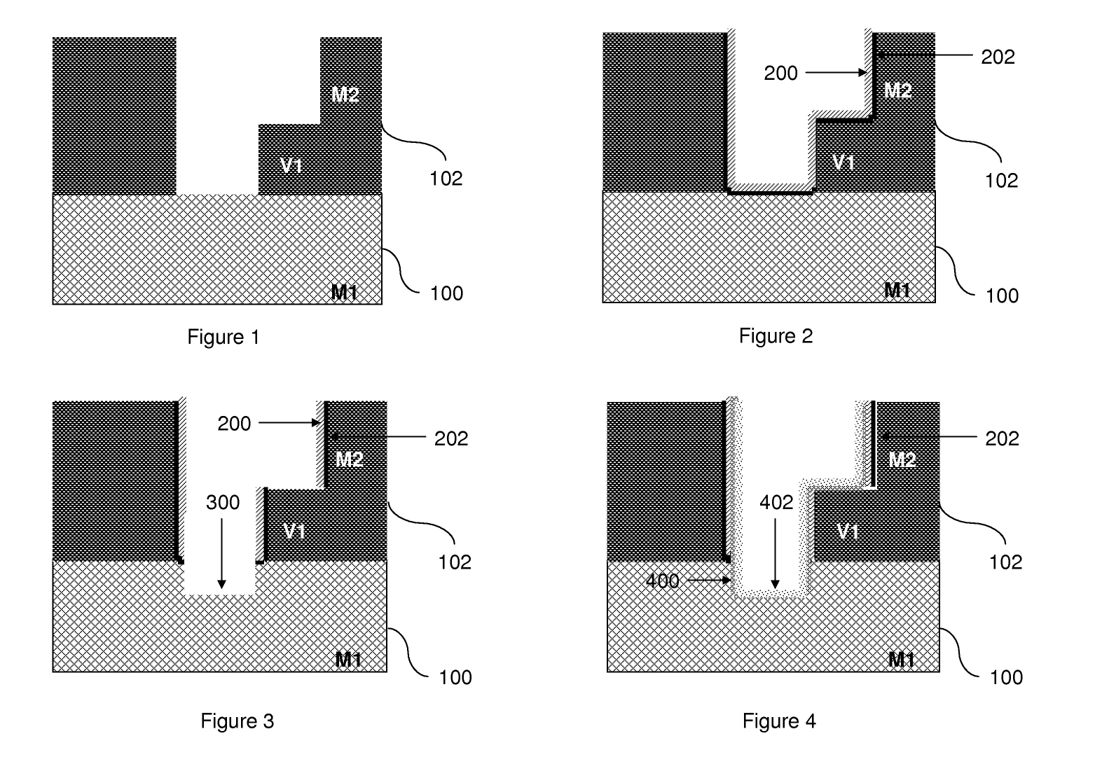

Referring now to the drawings, as shown in FIGS. 1-4, an insulator 102 is positioned over a first metallization layer 100. The insulator layer 102 is patterned for a second layer of wiring (M2) and a via connection (V1) to the first metallization layer 100. FIG. 2 illustrates the initial layer of TaN 202 and Ta 200 that are conformally deposited. Then, a sputter etch is performed to produce a deeper recess 300 into the first metallization layer 100.

In FIG. 3, the embodiments herein make a second TaN deposition 400 to line the recess prior to any Ta or Ta:Ru deposition (immediately after the Ar+ sputter etch). This is optimal for barrier performance (shown, e.g. in oxidation testing), and for formation of low-resistivity alpha-Ta for current redundancy. The embodiments herein follow the post-argon-sputter-etch-TaN deposition 400 with a Ta layer 402 such that the post Ar-sputter clean structure is exposed to a second bilayer (TaN/Ta). This preserves the optimal barrier properties of the TaN/dielectric interface at all points on the structure, as well as the optimal alpha-Ta formation. Significant barrier and electromigration improvements are thereby achieved with this method and structure.

Stated generally, the disclosed method forms a via between metallization layers in a semiconductor structure by patterning an insulator layer overlying a first metallization layer to include a via opening. The method lines the via opening with TaN and Ta liners and then sputter etches the via opening deeper through the TaN and Ta liners into the first metallization layer. After sputter etching, the method then lines the via opening with second TaN and Ta liners. Next, a conductor is deposited into the via opening, thereby connecting the first and second metallization layers.

Alternatively, we can make the TaN/Ta bilayer 400/402, post Ar+sputter etch, into a more sophisticated Ta/TaN/Ta trilayer, if the Ta layer on the bottom provides sufficient interfacial resistance advantage. Another alternative deposition sequence following the punch-thru etch would be a TaN/Ru or TaN/Ru—Ta alloy deposition in order to preserve both the barrier advantages of the TaN around the dielectric/barrier interface, as well as the improved wettability and fill characteristics of the Ru and/or Ta-PGM alloy relative to the copper seedlayer/Cu Fill material.

Further, embodiments herein can integrate Ru as redundancy/direct plating layer. Materials such as Ru, PGMetals, and Ta/PGM alloys are being considered as replacement for Ta-only redundancy layers due to better wettability of Cu and can be used with embodiments herein. One associated issue is that Ru, Ta/Ru alloys are poor barrier materials. Another option for the liner is TaN/Ru or TaN/(Ta:Ru alloy) which preserves barrier integrity with a punch-thru scheme, while enabling PGM redundancy layer integration.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

What is claimed is:

1. A method of forming a via between metallization layers in a semiconductor structure, said method comprising:
patterning an insulator layer overlying a first metallization layer to include a via opening;
lining said via opening with first and second liners;
sputter etching said via opening through said first and second liners into said first metallization layer;
lining said via opening with third and fourth liners; and
depositing a conductor in said via opening.

2. The method according to claim 1, wherein lining of said via with said third and fourth liners further comprises lining said via with a fifth liner.

3. The method according to claim 1, wherein lining of said via with said third and fourth liners further comprises lining said via with an alloy of different materials.

4. A method of forming a via between metallization layers in a semiconductor structure, said method comprising:
patterning an insulator layer overlying a first metallization layer to include a via opening;
lining said via opening with TaN and Ta liners;
sputter etching said via opening through said TaN and Ta liners into said first metallization layer;
lining said via opening with second TaN and Ta liners; and
depositing a conductor in said via opening.

5. The method according to claim 4, wherein lining of said via with said second TaN and Ta liners further comprises lining said via with a Ta/TaN/Ta liner.

6. The method according to claim 4, wherein lining of said via with said second TaN and Ta liners further comprises lining said via with an alloy of different materials.
